(19) United States
(12) Patent Application Publication
(10) Pub. No.: US 2025/0384498 A1
(43) Pub. Date: Dec. 18, 2025

(54) AI ASSISTED REAL ESTATE LISTING

(71) Applicant: CoreLogic Solutions, LLC, Irvine, CA (US)

(72) Inventors: Marc-Antoine Juanéda, Campbell River (CA); David Hamilton, Mission Viejo, CA (US)

(21) Appl. No.: 19/234,078

(22) Filed: Jun. 10, 2025

Related U.S. Application Data
(60) Provisional application No. 63/659,191, filed on Jun. 12, 2024.
(60) Provisional application No. 63/663,599, filed on Jun. 24, 2024.

(51) Int. Cl. G06Q 50/16; G06T 11/20; G06T 17/00; G06V 10/70

(52) U.S. Cl. CPC G06Q 50/16; G06T 11/203; G06T 17/00; G06V 10/70; G06T 2200/24

(57) ABSTRACT

A system may receive a request to generate a property listing for a property. The system may access additional information associated with the property. The system may generate a prompt for a machine learning model to cause the machine learning model to generate the property listing. The property listing may be a high quality listing that conforms to the requirements of a multiple listing service, does not contain incorrect or inconsistent information, and is written to improve the likelihood of attracting attention on the multiple listing service. The system may provide the generated property listing to a user for approval, and once approved make the property listing publicly available.

### CROSS-REFERENCE TO RELATED APPLICATIONS

This application claims priority under 35 U.S.C. § 119 (e) to U.S. Provisional Application No. 63/659,191, filed Jun. 12, 2024, and titled “MACHINE LEARNING-BASED PROPERTY LISTING GENERATION,” and U.S. Provisional Application No. 63/663,599, filed Jun. 24, 2024, and titled “MACHINE LEARNING-BASED PROPERTY LISTING GENERATION,” which are hereby incorporated by reference herein in their entirety.

### BACKGROUND

Property listing services, such as multiple listing services, may include listings for many different properties. An entity associated with a property to be sold may want to list the property on a multiple listing service. The entity may then write a property listing for the property, and publish the property listing to the multiple listing service.

### SUMMARY

In some aspects, the techniques described herein relate to a computer-implemented method including: receiving property information; generating a prompt for a machine learning model including at least a portion of the property information; applying the prompt as input to a machine learning model to cause the machine learning model to generate property listing information; transmitting the property listing information; based on transmitting the property listing information, receiving a response associated with the property listing information; based on the response, modifying the prompt to generate a modified prompt; applying the modified prompt as input to the machine learning model to cause the machine learning model to generate updated property listing information; and automatically updating a property listing based on the updated property listing information.

The computer-implemented method of the preceding paragraph can include any sub-combination of the following features: generating information to cause display of a graphical user interface; and receiving, via the graphical user interface, an image including image information for a portion of a property, where the property information includes the image information, where the image information includes LIDAR information generated by a LIDAR of a user device, generating a floor plan based on image information, where the floor plan is generated, based in part, on the image, and where the property information further includes the floor plan, receiving a first image including image information for a first portion of a room of a structure; generating a first portion of a model of the room based on the first image, based on the generated first portion, displaying, via the user interface, an instruction indicating a user is to capture a second image including image information for a second portion of the room, where at least a portion of the second image is different from the first image; receiving the second image; generating a second portion of the model of the room based in part on the second image and the first portion of the model; combining the first portion and the second portion of the model of the room to generate a combined model, and displaying, via the user interface, the combined model, where the first image includes first image information generated by a camera, and where the second image includes second image information generated by a LIDAR, identifying, based on at least one of the first image or the second image, at least one of an appliance or fixture in the room, applying the image information as input to a second machine learning model trained to identify fixtures represented in image information to cause the second machine learning to identify a fixture represented in the image, and based on the identified fixture, generating second property listing information; receiving a user utterance as audio information, where the second machine learning model is a multimodal model, where the second machine learning model is further trained to identify fixtures based on multimodal input information, where applying the image information as input to the second machine learning model further includes applying the audio information as input to the second machine learning model, and where the fixture is further identified based in part on the audio information; where the response includes second property information associated with the property information, where the property information is in a first modality, and where the second property information is in a second modality different from the first modality.

In some aspects, the techniques described herein relate to a system including: a computer-readable memory that store computer-executable instructions; and one or more processors in communication with the memory, where the computer-executable instructions, when executed by the one or more processors, causes the one or more processors to at least: receive property information; generate a prompt for a machine learning model including at least a portion of the property information; apply the prompt as input to a machine learning model to cause the machine learning model to generate property listing information; transmit the property listing information; based transmitting the property listing information, receive a response associated with the property listing information; based on the response, modify the prompt to generate a modified prompt; apply the modified prompt as input to the machine learning model to cause the machine learning model to generate updated property listing information; and automatically update a property listing based on the updated property listing information.

The system of the preceding paragraph can include any sub-combination of the following features: where the computer-executable instructions, when executed, further cause the one or more processors to generate information to cause display of a graphical user interface, and receive, via the graphical user interface, an image including image information for a portion of a property, where the property information includes the image information; where the computer-executable instructions, when executed, further cause the one or more processors to receive a first image including image information for a first portion of a room of a structure, generate, based on the first image, a first portion of a model of the room; based on the generated first portion, display, via the user interface, an instruction indicating a user is to capture a second image including image information for a second portion of the room, where at least a portion of the second image is different from the first image, receive the second image, generate, based in part on the second image, a second portion of the model of the room, combine the first portion and the second portion of the model of the room to generate a combined model, and display, via the user interface, the combined model; where the first image includes image information generated by a camera, and where the second image includes image information generated by a LIDAR; where the image information includes LIDAR information generated by a LIDAR of a user device; where the instructions, when executed by the processor, cause the computing device to at least: receive property information; generate a prompt for a machine learning model including at least a portion of the property information, apply the prompt as input to a machine learning model to cause the machine learning model to generate property listing information, transmit the property listing information; based transmitting the property listing information, receive a response associated with the property listing information, based on the response, modify the prompt to generate a modified prompt, apply the modified prompt as input to the machine learning model to cause the machine learning model to generate updated property listing information, and automatically update a property listing based on the updated property listing information; where the instructions, when executed by the processor, further cause the device to generate information to cause display of a graphical user interface, and receive, via the graphical user interface, an image including image information for a portion of a property, where the property information includes the image information; where the instructions, when executed by the processor, further cause the device to: apply the image information as input to a second machine learning model trained to identify fixtures represented in image information to cause the second machine learning to identify a fixture represented in the image, and based on the identified fixture, generate second property listing information.

In some aspects, the techniques described herein relate to a non-transitory machine-readable storage medium, where the instructions, when executed by the processor, further cause the device to receive a user utterance as audio information, where the second machine learning model is a multimodal model, where the second machine learning model is further trained to identify fixtures based on multimodal input information, where applying the image information as input to the second machine learning model further includes applying the audio information as input to the second machine learning model, and where the fixture is further identified based in part on the audio information.

The non-transitory machine-readable medium of the preceding paragraph can include any sub-combination of the following features: where the response includes second property information associated with the property information, where the property information is in a first modality, and where the second property information is in a second modality different from the first modality; generate information to cause display of a graphical user interface, and receive, via the graphical user interface, an image comprising image information for a portion of a property, wherein the property information comprises the image information; apply the image information as input to a second machine learning model trained to identify fixtures represented in image information to cause the second machine learning to identify a fixture represented in the image, and based on the identified fixture, generate second property listing information; receive a user utterance as audio information, where the second machine learning model is a multimodal model, where the second machine learning model is further trained to identify fixtures based on multimodal input information, where applying the image information as input to the second machine learning model further comprises applying the audio information as input to the second machine learning model, and where the fixture is further identified based in part on the audio information; where the response comprises second property information associated with the property information, where the property information is in a first modality, and where the second property information is in a second modality different from the first modality.

### BRIEF DESCRIPTION OF THE DRAWINGS

Embodiments of various inventive features will now be described with reference to the following drawings. Throughout the drawings, reference numbers may be re-used to indicate correspondence between referenced elements. The drawings are provided to illustrate example embodiments described herein and are not intended to limit the scope of the disclosure. To easily identify the discussion of any particular element or act, the most significant digit(s) in a reference number typically refers to the figure number in which that element is first introduced.

FIG. 1 is a block diagram of illustrative environment for generating a property listing using a property listing generation system according to some embodiments.

FIG. 2 is a block diagram of an illustrative operating environment for a property listing generation system according to some embodiments.

FIG. 3 is a block diagram of illustrative data flows for a property listing generation system according to some embodiments.

FIG. 4 is an illustrative routine for generating a property listing using a property listing generation system according to some embodiments.

FIG. 5 is a block diagram of an illustrative computing system configured to provide generation of a property listing according to some embodiments.

FIG. 6 is an illustrative example of a user interface presenting a property listing generated by the property listing generation system according to some embodiments.

FIG. 7 is an illustrative example of a user interface for indicating a property listing generation has been completed according to some embodiments.

### DETAILED DESCRIPTION

The present disclosure relates to the automated generation of property listing information using a machine learning model-based system. The property listing generation system can direct a user (e.g., a property seller, a real estate professional working on behalf of a property seller, etc.) in providing, accessing, and recording information (e.g., images, videos, audio, etc.) that may be useful for generating property listing information that may be used in a property listing. The directions provided by the property listing generation system may include a voice or text conversation between the property listing generation system and a user, for example through a user device. The directions may guide or assist a user in generating light detection and ranging (LIDAR) or image information for at least a portion of a property. The property listing generation system may then access additional information related to the property and neighborhood where the property is located (e.g., census information, zoning information, structure type, prior sales information, assessed property value information, rental information, ZIP code information, housing information, geometric property information, lien information, socioeconomic information, etc.). Using the accessed and received information, the property listing generation system may generate a prompt for a machine learning model to cause the machine learning model to generate property listing information. The property listing information may be generated according to a format used by a multiple listing service. The property listing generation system may then provide the generated property listing information to the user for approval, for example through an interface provided by the property listing generation system or through an interface provided by the multiple listing service.

Some conventional systems allow for a seller of a property, or user associated with the seller (e.g., seller's agent) to prepare a property listing for selling, renting, or otherwise transferring an interest in a property. However, such property listings vary widely in quality. Several aspects may affect the quality of a property listing. For example, a lower quality property listing may be one that leads a property to have a longer than average time on the market, includes errors (e.g., incorrect property information, incorrect dates, incorrect home owners association fees, incorrect taxes, an incorrect school district, etc.), violates a format requirement of the multiple listing service, includes typographical errors, includes poor quality or non-representative images of the property, or otherwise fails to properly conform to the requirements of the multiple listing service while correctly informing a user of the multiple listing service of property information. Additionally, a property listing may be of lower quality because it lacks an element (e.g., a virtual tour, floor plans, a listing of appliances, etc.), includes incorrect property listing information, includes a property description that is not engaging to a potential purchaser, or fails to successfully reflect positive aspects of the property in an engaging manner. A lower quality property listing may result in less engagement from consumers on a public portal (e.g., a real estate listing website), leading to a lower overall sale price than might otherwise have been achieved and a longer average time listed for sale.

Additionally, generating a property listing may involve multiple different steps, and these steps may be unrelated. For example, as part of creating a property listing an agent may record video or images to generate a virtual tour, a floor plan, a listing of appliances, or to include images in the property listing. The images or video necessary to generate a useful virtual tour (e.g., a virtual tour of all intended areas of the property that allows for smooth transitions between areas) may be challenging to capture without instruction and feedback. Further, property listings may contain property images, and an agent may need to wait for a current owner of the property to prepare the property for such images to be captured, or the agent may need to stage the property. The process of preparing the property to be photographed may be time consuming and lead to delays in listing the property.

Further, when images for a virtual tour and images for a property listing are taken at different times, changes may have occurred to the property (e.g., a current owner rearranging furniture, painting of a portion of the property to prepare for sale, etc.) and a buyer seeing these changes may be confused as to which images represent the current state of the property. Additionally, preparing a floorplan, or gathering accurate measurements of the interior of a structure (e.g., the dimensions of individual rooms) using current methods may be time-consuming and involve manual measurement of at least a portion of a structure. For example, a listing agent or seller may know the overall length of the structure, but not the length of individual rooms within the structure. In order to accurately determine the size of different portions of the structure, the listing agent or seller may have to measure individual rooms by hand using a measuring tape or laser measuring device. Each of these methods may be limited in their accuracy. For example, furniture, structural elements (e.g., a wall, a post, a door, etc.) or temporary elements (e.g., moving boxes, a parked car, etc.) may limit the ability of an individual to reach certain areas of a property with a measurement device. The result is that in some cases, a listing agent or seller will guess the size of at least one room of a structure on a property based on information provided by a builder or previous seller, or may opt not to provide interior dimensions in the listing. In either case, the result is a lower quality listing that may result in reduced interest in the property. Further, some systems may use photogrammetry to attempt to estimate interior dimensions, however photogrammetry may be limited when objects are present in portions of the room that are imaged, resulting in inaccurate dimensions for the room, or increased computational resources to then estimate the size of each object obstructing the measurement.

Additionally, photogrammetry or other current methods of image-based or LIDAR-based measurement may be computationally inefficient and require information to be transferred to a remote system that may be operated by a third-party. Such information transfer to a remote system may negatively impact the privacy of the user, the privacy of the homeowner. Further processing the amount of data involved in estimating interior dimensions and generating a floorplan, virtual model, or virtual tour may require significant network and computer resources to achieve.

Further, generating a property listing may involve a seller or agent drafting a text description of the property. This text description may be internally inconsistent (e.g., listing inconsistent values for the square footage), which may discourage potential buyers from expressing interest. The prose of a property listing may also be poorly written (e.g., having spelling errors, having poor formatting, having grammatical errors, failing to include positive aspects of the property or emphasizing negative aspects of the property, etc.) lowering the ability of the property listing to attract attention from potential buyers.

Some aspects of the present disclosure address some or all of the issues noted above, among others, by providing for interactive and automated generation of property listing information for a property listing using an automated property listing generation system. The property listing generation system may allow a seller or seller's agent to generate individual elements of a property listing (e.g., property listing information), or an entire property listing at a single time (e.g., without repeated visits for staging or measurement). The property listing information generated by the automated property listing generation system may be used to create a high quality property listing conforming to the format of a multiple listing service and following a format determined by the property listing generation system to represent a high quality property listing (e.g., based on training a machine learning model to generate property listing information using identified high quality listings already present on the multiple listing service, or high quality listings generated automatically for use in training the machine learning model, as representative of a preferred output of the machine learning model). A high quality listing may refer to a property listing that tends to lead to the sale, lease, rental, or other transfer of an interest in the associated property within a shorter timeframe than other property listings associated with similar properties. The high quality property listing information generated by the listing generation system may also include a text description that is written using terms, or prose, determined based on analysis of previous property listings to be likely to improve the speed at which the property is sold, for example by engaging a reader of the property description. Additionally, a listing score may be provided to a user indicating a quality rating of the property listing or property listing information determined based on the content of a listing. The listing score may be accompanied by recommendations on how to improve the score, thereby engaging additional interested purchasers and improving the overall likelihood of the property being sold.

In some embodiments, a property listing generation system includes a machine learning model trained to generate high quality property listings. The machine learning model may be provided by a separate machine learning model provider. The machine learning model may be provided to a user device. The machine learning model may be trained for a specific multiple listing service format. Alternatively, the format of the property listing may be provided as part of the input to the machine learning model when generating a property listing. The machine learning model may additionally be trained based on previously-identified or generated high quality property listings in order to cause the machine learning model to generate new high quality property listings using data provided by a user or accessed by the property listing generation system.

The property listing generation system may provide an interactive user interface. The user interface may be a graphical user interface presented, for example, presented by a display of a user device and allowing interaction through the user device (e.g., by a keyboard or touchscreen). Additionally, an interface may be provided using a speaker and microphone of a user device to allow for conversational interaction between the property listing generation system and the user. For example, the user may initiate a connection to the property listing generation system through a user device. Initiating the connection may cause the user device to transmit a location of the property, or request the user to provide the location. The user may further interact with the property listing generation system to provide additional property information. Further, the property listing generation system may instruct the user to collect or provide additional property information. For example, the property listing generation system may instruct the user in capturing images of the property that may be useful for generating the property listing. In this example, the captured images may be used to generate a virtual tour of the property, estimate property information (e.g., square footage, appliances, number of windows, number of a type of room, property condition, necessary repairs, room dimensions, room type, etc.), or be included in the property listing. Examples of room types that may be identified include a kitchen, bedroom, bathroom, and the like. In some embodiments, information about the property may be captured using a LIDAR, or other distance-measurement system, to estimate property information such as room dimensions, and the property listing generation system may instruct a user in the capture of the information using the LIDAR system. Property condition may include the condition of a portion of the property, such as the roof, and may indicate a likelihood of a future repair or replacement becoming necessary. Additionally, the property listing generation system may use information (e.g., images, LIDAR readings, audio description, etc.) provided by the user to estimate a potential increase in property value related to potential renovations (e.g., roof replacement, appliance replacement, foundation repair, repainting of the exterior, etc.).

In some embodiments, the property listing generation system may generate a floorplan or other representation of at least a portion of a structure on a property. The property listing generation system may generate a floorplan, virtual model (e.g., a three-dimensional model), or other representation of at least a portion of a property (e.g., a room in a house, a floor of a house, an entire structure on the property, the grounds surrounding a structure on the property, etc.). Further, the property listing generation system may include a machine learning model trained to determine a room type of a room during measurement or information capture, or based on generated image information. The generated image information may be the same image information used to generate the floorplan or other representation. The machine learning model, or another machine learning model provided by the property listing generation system, may be trained to identify a fixture, fixture type, furniture, furniture type, or other information associated with the structure from the image information. The machine learning model may be provided by a separate machine learning model provider. The machine learning model may be provided to a user device such that information used to generate the floorplan, virtual model, or other representation of the property may be processed locally by the user device and applied as input to the machine learning model to determine a room type, identify fixtures in a room, identify furniture in a room, or generate other determinations related to the information used to generate the floorplan or other representation of the interior of the structure. For example, a user may generate, by the user's device, image information (e.g., generated by a camera or LIDAR sensor of the user device). The property listing generation system may provide the user's device information to generate a floorplan, three-dimensional model, or other representation of the interior of a structure.

The property listing generation system may further provide a machine learning model to the user device to allow the user device to apply generated or received information as input to the machine learning model to cause the machine learning model to generate information associated with at least a portion of the structure (e.g., determining a room type of a portion of the floorplan or three-dimensional model, identifying a fixture type, identifying furniture, etc.). In some embodiments, the system may provide a graphical user interface to display the generated floorplan, virtual model, or other representation during generation (e.g., portions may be displayed as they are generated from information provided as input to the machine learning model) via a display of the user device. The user interface may be the graphical user interface described above. Such a display may be used to assist the user in generating a complete representation of an area by indicating portions of the area that have previously been imaged and converted to a floor plan or other representation, or by indicating portions of the area that have not yet been imaged by a camera or LIDAR element of the user device or for which additional image information may be useful in generating accurate information. The graphical user interface may be presented as an augmented reality where a camera of the user device enables visualization of an area where the camera is currently directed, and the image is further overlaid with information useful in assisting the user in generating image information for completing the floor plan or other representation of the interior of the structure. For example, a current image generated by the camera of the user device may be displayed in the graphical user interface. The current image may be overlaid with highlighting, lines, or other visual elements to indicate that a portion of the image has been identified by a machine learning model as being a type of fixture in the structure, or a type of furniture. Further, in this example, lines may be overlaid on the current image indicating the portion of the current image that has been converted to a floorplan or other representation of the area.

Additionally, the property listing generation system may access property information, including neighborhood information, stored in a data services system, such as a data services system maintained by a property information provider. The accessed property information may include, for example, past sales prices, past offers, current offers, lien information, tax information, ZIP code information, socioeconomic information, census information, assessed property value, rental history information, wildfire risk, flood risk, other hazard (e.g., hurricane, wind, earthquake, tornado, etc.) risk, address information, school zone, park access, walkability score, proximity to transit, and the like. The property listing generation system may also access a machine learning model, that may be provided by a separate machine learning model provider, in order to generate additional property information. For example, the square footage estimate based on captured images noted above may be generated by a machine learning model in response to a request included the user-provided images as input. A machine learning model may also be used to caption an image, classify an image, or identify objects in an image. While reference to an image is used in the preceding example, it should be noted that video, multimodal, or other information types may be provided as input to a machine learning model to generate such information. For example, audio of a conversation between the property listing generation system and a user may be provided as input to a machine learning model to generate a transcript and at least a portion or summary of the transcript may be included when generating the prompt to cause generation of the property listing by a machine learning model.

The property listing generation system may also use a machine learning model to improve the quality or relevant of an image or video of the associated property. For example, a user may provide an image of a room within a house. The property listing generation system may then detect a part of the property represented in the image (e.g., exterior, roof, bedroom, backyard, living room, kitchen, etc.). The image of the room may include personal items of the owner. However, displaying such personal items in a publicly available property listing may be undesirable. The property listing generation system may then apply the image as input to a machine learning model to remove the personal items from the image, thereby generating an improved image for use in the property listing. Additionally, in this example, the property listing generation system may identify characteristics relevant to the property listing, or a format used by a listing service, such as appliances, interior features (e.g., crown molding, French door, etc.) and include such information in a generated property listing. In another example, a user may provide an exterior image of a property taken on a rainy day to the property listing generation system. The property listing generation system may then use a machine learning model to alter the image to show the property on a sunny day instead while maintaining an accurate representation of the property. In a further example, an agent may photograph the property without having staged the property (e.g., on an initial visit) and the property listing generation system may alter the images to stage the property for the listing while maintaining an accurate representation of the property, thereby minimizing the time and number of visits required to publicly list the property.

The property listing generation system may then use the generated, received, and accessed information related to the property to generate a prompt for a machine learning model configured to generate property listing information. The prompt may include some or all of the generated, received, or accessed information. For example, some information may be determined to be redundant and excluded from the prompt. In another example, conflicting information may be received, and the property listing generation system may select the information from a source determined to be more reliable. For example, a room dimension estimate generated based on images or LIDAR information captured by the user at the property may conflict with a room dimension estimate in historical sales information for the property accessed from a data services system. The property listing generation system may determine the historical sales information is more likely to have the correct room dimensions, and omit the generated room dimension estimate from the information provided to the machine learning model to generate the property listing information.

When the property listing generation system receives the generated property listing information from the machine learning model, the property listing generation system may transmit the generated property listing information to the user (e.g., to the user device), or to the multiple listing service. The user may then accept the property listing information. In some embodiments, the property listing information may be combined (e.g., with additional property listing information generated by a machine learning model, a user, or accessed from another system) to generate a property listing. In such embodiments, the property listing may be accepted by the user causing the property listing to be publicly displayed on the multiple listing service, or the user may provide additional feedback to be incorporated into the property listing. The property listing generation system may then regenerate the property listing, or individual property listing information, based on the additional feedback, for example by updating the prompt to include the additional feedback. The property listing generation system may also ensure that the additional feedback does not cause the generated property listing information to violate a rule of the multiple listing service, and inform the user if the additional feedback would cause such a violation. The feedback may be received through the interface presented through the user device, for example the graphical user interface or the conversational user interface using the user device's microphone and speaker.

Further, the property listing may include a virtual tour of the property. The virtual tour may be generated by the property listing generation system using a machine learning model, or a rules-based system, and may incorporate the images or video provided by the user. The property listing generation system may determine that an additional image or video would be helpful in generating the virtual tour, and request the user to capture such an image or video. The property listing generation system may provide an interactive interface to assist the user in capturing the additional image or video. The virtual tour may be generated for use with a virtual reality, or augmented reality, display and interaction system. The property listing generation system may also determine a score associated with a determined quality of the property listing, and provide the score to a user along with suggestions on how to improve the score (e.g., advertising through a digital marketing channel, improving a picture of the property, including a virtual tour, etc.).

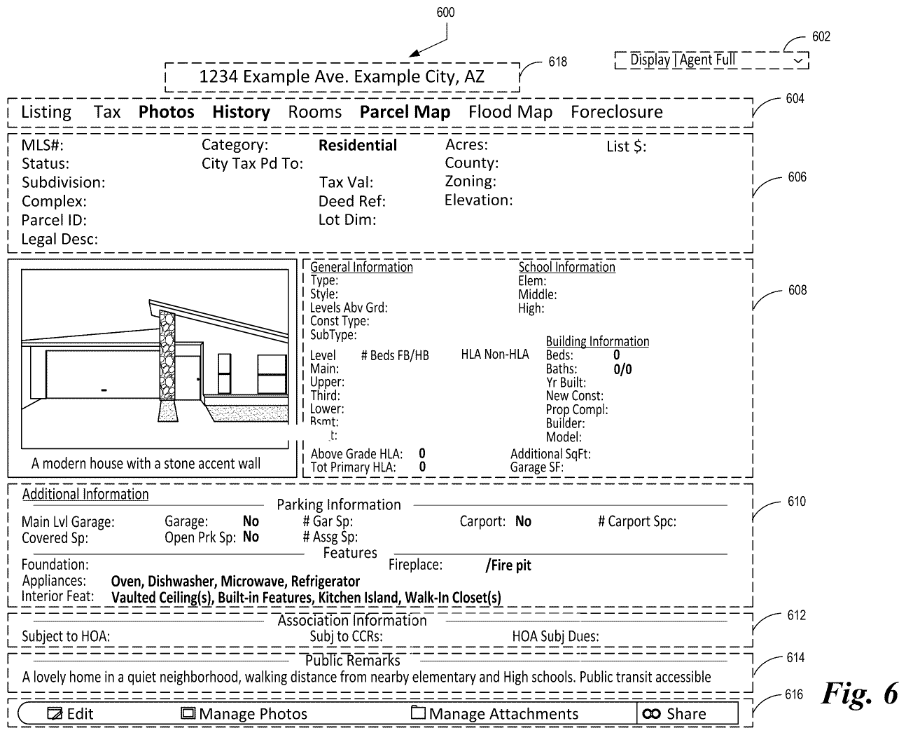

Property listing information, as used herein, may refer to information that may be presented as part of a property listing (e.g., a property listing accessible through a multiple listing service). It should be understood that referring to property listing information, or a property listing, may be done individually (e.g., by referring only to a property listing or property listing information) throughout the description herein, this is to assist with understanding of the description and is not intended to limit such description to the generation of one or the other. Instead, the systems and methods described herein may be applied to generate individual elements of property listing information, or a property listing as a whole. Examples of property listing information include zoning, elevation, tax value, county, structure type, number of structure levels, number of bedrooms, number of bathrooms, garage type, parking availability, elevator access, lot size, home owners associate (HOA) information, a natural language description of the property, or any other information that may be included in a property listing (e.g., based on the listing service where the property listing will be stored). Further examples are included in FIG. 6 below herein.

Certain aspects and implementations are discussed herein with reference to use of a machine learning (ML) model, those aspects and implementations may be performed by any other artificial intelligence (AI) model, generative AI model, generative model, language model, large language model, transformer-based vision model, neural network (NN), deep-learning NN, multimodal model, and/or other algorithmic processes. Examples of models, that may be used in various implementations of the present disclosure include, for example, feed-forward NNs, NNs having one or more fully connected layers, large language models (e.g., Llama, GPT, Claude, etc.), graph neural networks (GNNs), Bidirectional Encoder Representations from Transformers (BERT), and the like.

Various aspects of the disclosure will be described with regard to certain examples and embodiments, which are intended to illustrate but not limit the disclosure. Although aspects of some embodiments described in the disclosure will focus, for the purpose of illustration, on particular examples of machine learning models, information modalities, and the like, the examples are illustrative only and are not intended to be limiting. In some embodiments, the techniques described herein may be applied to additional or alternative types of machine learning models, information modalities, and the like. Additionally, any feature used in any embodiment described herein may be used in any combination with any other feature or in any other embodiment, without limitation.

### Example Listing Generation System Environments

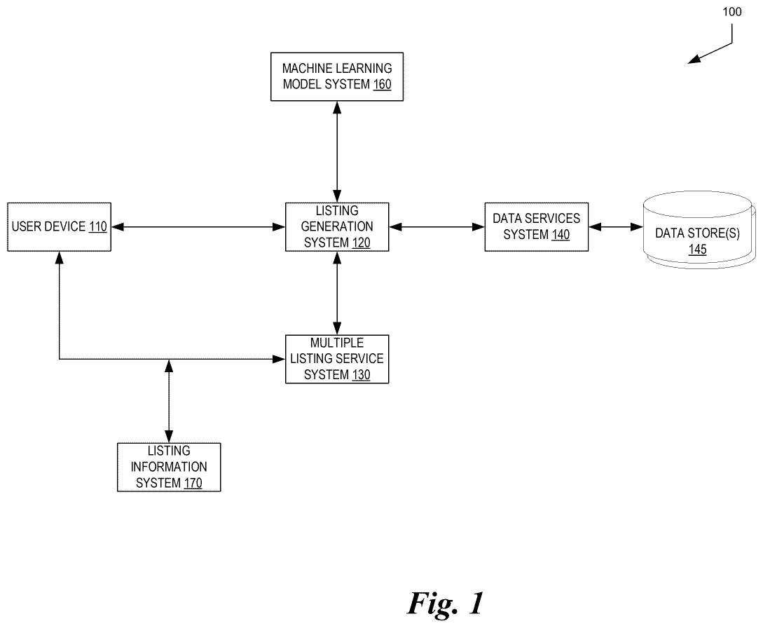

With reference to an illustrative example, FIG. 1 shows an illustrative environment 100. The environment 100 comprises a user device 110, a listing generation system 120, a multiple listing service system 130, a data services system 140, a machine learning model system 160, and a listing information system 170. While the components of this example environment 100 are discussed here individually, it should be understood that some or all of these components may operate on the same device.

The user device 110 is a computing device that may be associated with a user. For example, the user device 110 may be a mobile computing device, a smartphone, a laptop computing device, a desktop computing device, or a device providing computing resources through communication with a server computing device (e.g., a terminal device providing access to a server through a network). The user device 110 may include a camera, a microphone, a display, a speaker, and an additional input (e.g., a touch screen, a keyboard, etc.).

The listing generation system 120 is configured to generate property listing information, or a property listing. The property listing information may be formatted according to the requirements of a listing service, for example based on information received from the user device 110 and additional property information accessible to the listing generation system 120. The listing generation system 120 may further be configured to generate, modify, or analyze images associated with a property, for example using a machine learning model. Images, as used herein, may include image information generated by a camera of the user device 110, or LIDAR information generated by a LIDAR module of the user device 110. The listing generation system 120 may further provide information (e.g., information to generate a user interface, a machine learning model, etc.) to the user device 110 to enable additional functionality of the user device 110. Such additional functionality may be useful for generating property listing information.

For example, the listing generation system 120 may provide a user interface and machine learning model to the user device 110 to enable the user device 110 to generate a floor plan or virtual model based on image information generated by a camera or LIDAR of the user device 110. In this example, the listing generation system 120 may further provide information to generate a user interface on a display of the user device 110 to allow the user to observe the generation of the floor plan or virtual model as portions of the floor plan or virtual model are generated. Such a display may assist the user in ensuring that an entire area for which a floor plan or virtual model is to be generated has been generated (e.g., by allowing the user to determine a portion of the area is missing from the floor plan or virtual model). In some embodiments, the display may assist a user in capturing property listing information (e.g., dimensions of a room of a structure) by directing the user to capture image information via a camera or LIDAR of the user device 110 for an area for which property listing information has yet to be generated, or for which additional information may assist in generating accurate property information. The user interface may be presented as an augmented reality user interface incorporating a current image of an area with generated imagery indicating generated property listing information overlaid on the current image. For example, if a current image displays a wall of a room, the augmented reality user interface may indicate a length of the wall and a room type overlaid on the image of the wall. In another example, if a current image displays a first portion of a room, the augmented reality user interface may overlay lines, highlights, or other visual indicators on the current image of the first portion of the room to indicate sub-portions of the first portion that have been processed from the current image or previously-generated images to determine property listing information. Further, the generated property listing information may be overlaid on the current image to allow a user to review the generated property listing information in the context of the current image to more readily identify potential errors.

The multiple listing service system 130 is configured to allow users to upload, search, and access property listings. The multiple listing service system 130 may store the property listings, or otherwise provide access to a storage service storing the property listings. The multiple listing service system 130 may define a format for property listings. For example, the format of property listings available through the multiple listing service system 130 may require certain descriptors such as property classification (e.g., residential, rental, commercial, lease, income property, etc.), address, price, listing expiration date, broker fees, participating brokers, any additional information required by a state or federal law, and the like. The format may also allow for certain optional descriptors, for example property size, number of a room type (e.g., bedroom, bathroom, kitchen, etc.), a room type (e.g., bedroom, living area, great room, garage, etc.), number of parking spaces, construction type, construction materials, date of construction, a date when a portion of a building on the property was last renovated or replaced, included appliances, heating, ventilation, and air conditioning (HVAC) availability, school district, access to transportation, access to amenities (e.g., a park, a mall, an entertainment venue, etc.), and the like. A multiple listing service system 130 may also require that a property listing provide accurate information.

As noted herein, providing a high quality and/or accurate property listing may be challenging to generate and the listing generation system 120 may be used to generate such a property listing, or property listing information to be included in a property listing, for the multiple listing service system 130. The listing generation system 120 may have access to an API, storage location, or other method of providing a generated property listing to the multiple listing service system 130. The multiple listing service system 130 may allow a user, for example a user associated with the user device 110, to approve of the property listing before the property listing is made public, or otherwise made available to an entity other than the user associated with the property listing.

The data services system 140 provides access to various types of property information related to individual properties as well as an area where a property is located (e.g., a school district, city, town, state, etc.). The data services system 140 is in communication with at least one data store 145 that stores the property information. The data services system 140 accesses the at least one data store 145 in response to a request for information, for example a request received from the listing generation system 120, and provides the requested information. The data services system 140 may determine which data store 145 to access for information based in part on the received request. In some embodiments, a first data store 145 may store one type of property information (e.g., store information related to school districts, electricity providers, rental values, etc.) that is different from the type of property information stored by a second data store 145. Alternatively, a first data store 145 may store property information for a first geographic area (e.g., a ZIP code, a county, a town, a census tract, etc.), and a second data store 145 may store property information for a second geographic area.

The machine learning model system 160 is configured to provide access to one or more machine learning models. The machine learning models may be of different types (e.g., a large language model, a classifier, etc.), and may be configured to accept different input modalities (e.g., text, images, video, audio, multimodal input, etc.). For example, a machine learning model may be capable of generating a description of an image. In another example, a machine learning model provided by the machine learning model system 160 may be configured to identify an object type (e.g., table, chair, pool, doorway, etc.). In a further example, a machine learning model provided by the machine learning model system 160 may be configured to generate a listing description for a property listing. The machine learning model may be trained to generate the listing description according to a format used by the multiple listing service system 130. Alternatively, the machine learning model may be trained to generate text generally, and may be instructed (e.g., as part of an input prompt) to generate text according to the format of the multiple listing service system 130. The prompt may be received by the machine learning model system 160 from the listing generation system 120. The machine learning model system 160 may add additional description to the prompt in order to cause a machine learning model to generate the desired output (e.g., limitations on profanity, information to limit the likelihood of hallucinated information being included in an output of the machine learning model, etc.).

The listing information system 170 provides access to various property listing services that may be separate from, or related to, a multiple listing service associated with the multiple listing service system 130. A listing service to which the listing information system 170 provides access may have a different listing format that that used by a multiple listing service associated with the listing information system 170. The listing generation system 120 may use the listing format of the listing information system 170 to modify a previously-generated property listing for the multiple listing service system 130. Alternatively, the listing generation system 120 may generate a new property listing for a listing service associated with the listing information system 170 based on the listing format of the listing service.

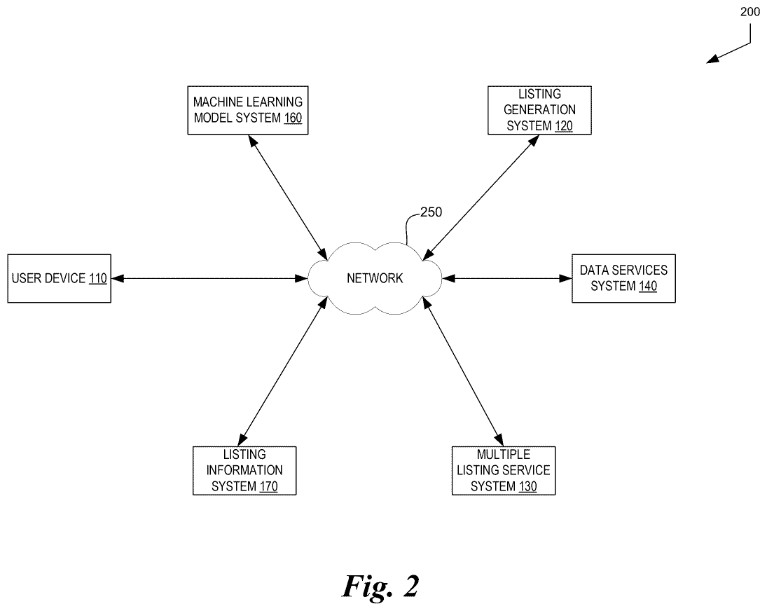

FIG. 2 illustrates example environment 200. The environment 200 comprises the user device 110, the listing generation system 120, the multiple listing service system 130, the data services system 140, the machine learning model system 160, and the listing information system 170 described in FIG. 1 above, and a network 250.

The network 250 may be any combination of a local area network (“LAN”) and/or a wireless area network (“WAN”) or the like. In some embodiments, the various components of the environment 100 may, in various implementations, communicate with one another directly or indirectly via any appropriate communications links (e.g., one or more communications links, one or more computer networks, one or more wired or wireless connections, the Internet, any combination of the foregoing, and/or the like).

### Example Property Listing Generation Process

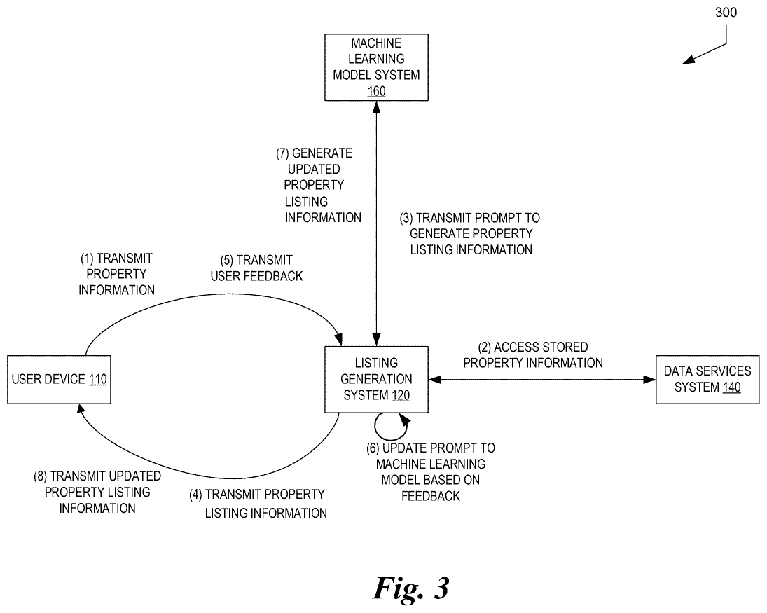

FIG. 3 illustrates an example process 300 for generating property listing information using the listing generation system 120. The process 300 starts at (1) where a user device 110 transmits property information to the listing generation system 120. The property information may include, for example, location information (e.g., an address, location data generated by a GPS system of the user device 110, an image from which a location may be determined, etc.), a property type identifier (e.g., rental, residential, condominium, lease, commercial, etc.), a listing price, descriptive information (e.g., a listing of appliances, square footage estimate, construction date, or other information that may be included in a property listing), or any other information the user believes may be useful for generating a property listing for the property. In some embodiments, the listing generation system 120 may request confirmation from the user device 110 that a property identifier or property location determined by the listing generation system 120 based on the received information is correct. Further, in some embodiments, the property information may include images of the property which may be used by the listing generation system 120 to access or generate property information for a property listing.

Additionally, an image of the property received from the user device 110 may be included in the property listing. In some embodiments, the listing generation system 120 may interact with the user device 110 in order to instruct a user of the user device 110 to capture specific images or video, or to capture images or video in a specific manner, to allow for improved generation of a property listing. The captured images may also be used to generate a virtual tour, allowing a viewer of the property listing to conduct a virtual walkthrough of the property on a computing device (e.g., a laptop, a smartphone, a projector in communication with a computing device, a virtual or augmented reality headset, etc.). To construct the virtual tour, the listing generation system 120 may provide instructions to the user device 110, for example text, image, or audio instructions, that are presented to the user and inform the user of how to properly capture images or video that are useful to the listing generation system 120. Additionally, the listing generation system 120 may use one or more images received from the user device 110 to determine information about the property. For example, the images may be used to determine a square footage of a room, building, or property. In another example, the images may be used to determine a number of room type (e.g., number of bedrooms, number of bathrooms, etc.).

Further, the property information received from the user device 110 may include at least a portion of a floorplan or virtual model of at least a portion of the property (e.g., a room of a structure, a floor of a structure, etc.). The floorplan or virtual model may be generated on the user device 110 by a machine learning model provided by the listing generation system 120. Further, a machine learning model provided to the user device 110 may automatically determine a room type associated with an image or floor plan and provide such property information to the listing generation system 120. The machine learning model may generate additional property information based on the image (e.g., generated by a camera or LIDAR of the user device 110). For example, a user may generate a LIDAR image of a part of a kitchen including an oven. The machine learning model may then automatically, based on the LIDAR image, determine that the area being imaged is a kitchen, and that an oven is present in the kitchen. The machine learning model may receive additional information from the user device 110, for example an utterance of the user provided as input to the model, to further refine the generated property image. An utterance may refer to a segment of voice information generated by a user that may include spoken words, phrases, and the like to convey meaning. Continuing the previous example, the user may have provided an utterance to the machine learning model indicating the presence of a convection oven in the kitchen. Based on the machine learning model determining the LIDAR image indicates the area from which the image was generated is a kitchen, that an oven is present in the LIDAR image, and the user utterance indicating a convection oven is located in the kitchen, the machine learning model may determine the oven in the LIDAR image is the convection oven and accurately label the portion of the LIDAR image representing the convection oven is a convention oven, or otherwise indicate the presence of the convection oven in generated property information. Such a combination of information from different sources in different modalities, the listing generation system 120 may provide the user device 110 with a machine learning model to generate property information having improved accuracy. Advantageously, generating property information in this way may reduce the amount of computing resources required to generate accurate property listing information as compared to previous methods.

At (2), the listing generation system 120 accesses property information stored by the data services system 140. To access the property information stored by the data services system 140, the listing generation system 120 may generate a request for information. The request may be generated based on the property information received from the user device 110. For example, the request may include an indication of a geographic area for which property information (e.g., school district, tax rate, homeowners association fees, etc.) is to be retrieved. The geographic area may be determined by the listing generation system 120 based on location data received from the user device 110. In another example, the request may be configured to cause the data services system 140 to provide historical pricing information for a property. The property may be determined by the listing generation system 120 based on the location data, for example by accessing map data to determine a property identifier (e.g., a street address or a business name) associated with the location data. Accessing property information stored by the data services system 140 may cause the data services system 140 to request the property information from at least one data store 145 in communication with the data services system 140. In some embodiments, the multiple listing service system 130 or a listing information system 170 may also act as a data services system 140 and provide information about the property, such as a previous listing, previous sale price, previous offer information, and the like.

At (3), the listing generation system 120 transmits a prompt to the machine learning model system 160 to cause a machine learning model of the machine learning model system 160 to generate property listing information. The listing generation system 120 may generate the prompt based on the information received from the user device 110, and the additional property information accessed from the data services system 140. For example, the prompt may include instructions to generate a property listing, or property listing information, and define the format of the property listing (e.g., a maximum length, a property information that should be included, a preferred tone, a preferred style, etc.). The prompt may further include at least a portion of the information accessed from the data services system 140. Additionally, the prompt may include an example of a property listing, or property listing information. The example of the property listing may be selected by a user of the listing generation system 120 or user device 110, for example a user may select a property listing that is associated with a property with which a favorable transaction occurred. As described previously herein, while many property listings may be available on a multiple listing service, a small percentage of such property listings are considered to be high quality listings. Therefore, the example property listing provided by the listing generation system 120 as part of the prompt may be a high quality listing.

In some embodiments, the machine learning model used to generate the property listing may have been trained to generate high quality property listings, for example by using identified high quality listings on a multiple listing service as training information for the machine learning model. In some embodiments, the machine learning model may be trained to generate property listing information for specific fields of a property listing based on a format of a property listing used by a multiple listing service system 130. The machine learning model may be trained to determine certain values for portions of a property listing (e.g., a room type, a structure type, a number of a room type, a type of appliance, etc.) based on training data. Further, the machine learning model may be a multimodal model trained to aggregate or combine information across various input modalities (e.g., text, image, audio, etc.) to generate accurate property listing information. For example, the machine learning model may process an image of an area and a voice note received from a seller or listing agent, and based on the combination of input information accurately determine property listing information for the property. In this way, a lack of information provided in a first input information (e.g., a single instance of an image, or all images) may be supplemented by information provided in a second input information (e.g., a second image, an utterance of a user, etc.).

The listing generation system 120 may transmit additional prompts or information to the machine learning model system 160. For example, the listing generation system 120 may transmit an image received from the user device 110 to the machine learning model system 160 so that a machine learning model may caption the image. A machine learning model of the machine learning model system 160 may also be used to classify the image (e.g., as a kitchen, a bathroom, a roof, an aerial image, etc.), or to identify objects visible in the image (e.g., a stove, an air conditioner, a clothes dryer, a sliding glass door, bay windows, etc.). In some embodiments, generating the property listing may be an iterative process, where the listing generation system 120 generates the prompt to cause the machine learning model system 160 to generate the property listing based on information received in response to a request from the listing generation system 120 to the machine learning model system 160 to caption or classify object in an image. The listing generation system 120 transmitting the prompt to generate the property listing causes the machine learning model system 160 to return the generated property listing to the listing generation system 120. While this example process 300 describes transmitting information to the machine learning model system 160, in some embodiments the listing generation system 120 may access a machine learning model of the machine learning model system 160 and provide the machine learning model to the user device 110 such that some or all of the execution of the machine learning model described herein is executed at the listing generation system 120 or the user device 110.

At (4), the listing generation system 120 transmits the generated property listing information to the user device 110, and may cause the user device 110 to display the property listing information for a user associated with the user device 110. The property listing information may be combined to generate a property listing. In some embodiments, the listing generation system 120 may transmit the generated property listing to the multiple listing service system 130, and the user may view the generated property listing by accessing the multiple listing service system 130.

At (5), the listing generation system 120 receives user feedback from the user device 110. The user feedback may, for example, indicate an error in the generated property listing or property information, a change to the generated property information (e.g., “replace the term living room with the term great room”), an indication of an error in the listing, a request to regenerate at least a portion of the property information in a different style, provide additional information that was not previously provided to the listing generation system 120 or accessed by the listing generation system 120 from the data services system 140, or any other feedback related to the generated listing. Additionally, the feedback may be in one or more modalities. For example, the feedback may be text feedback, audio feedback recorded by a microphone of the user device 110 and received by the listing generation system 120, image feedback as described previously, video feedback, or multimodal feedback. Alternatively, the user may indicate approval of the generated property listing and the listing generation system 120 may transmit the generated property listing to a multiple listing service system 130 or listing information system 170, or the process may end.

At (6), the listing generation system 120 generates an updated prompt for the machine learning model system 160 based on the feedback received from the user device 110 to the previously generated prompt or property listing information. For example, the listing generation system 120 may add to, or otherwise alter, the text of a prompt provided to the machine learning model system 160, add or remove images provided to the machine learning model system 160, or add, remove, or alter any other information provided as part of or along with the prompt to the machine learning model system 160 to cause generation of an updated property listing or updated property listing information. Additionally, where the feedback indicates that additional information may be accessed related to the property, the listing generation system 120 may access additional information from the data services system 140 and use such information to update the prompt.

At (7), the listing generation system 120 transmits the updated prompt to the machine learning model system 160 to cause the machine learning model system 160 to generate updated property listing information. As described in relation to (3), generating the updated property listing information may also include an iterative process where different machine learning models of the machine learning model system 160 generate information that will be used to generate the updated property listing information before generating the updated property listing information or an updated property listing. For example, if an additional image is included in the feedback received from the user device 110, the additional image may be provided to a captioning machine learning model to generate a caption for the image, a classifier machine learning model to classify the type of room shown in the image, or an image analysis machine learning model configured to identify types of objects shown in the image (e.g., appliances, doors, types of windows, fixtures, etc.). When the updated property listing has been generated, the machine learning model system 160 provides the updated property listing information to the listing generation system 120.

At (8), the listing generation system 120 transmits the updated property listing information to the user device 110 for approval or further feedback. While not shown, it should be understood that (5), (6), (7), and (8) may repeat until approval is received from the user device 110 for the generated property listing. When approval is received, the listing generation system 120 may transmit the generated property listing information, or a generated property listing, to a multiple listing service system 130 or other listing information system 170.

### Example Property Listing Generation Routine

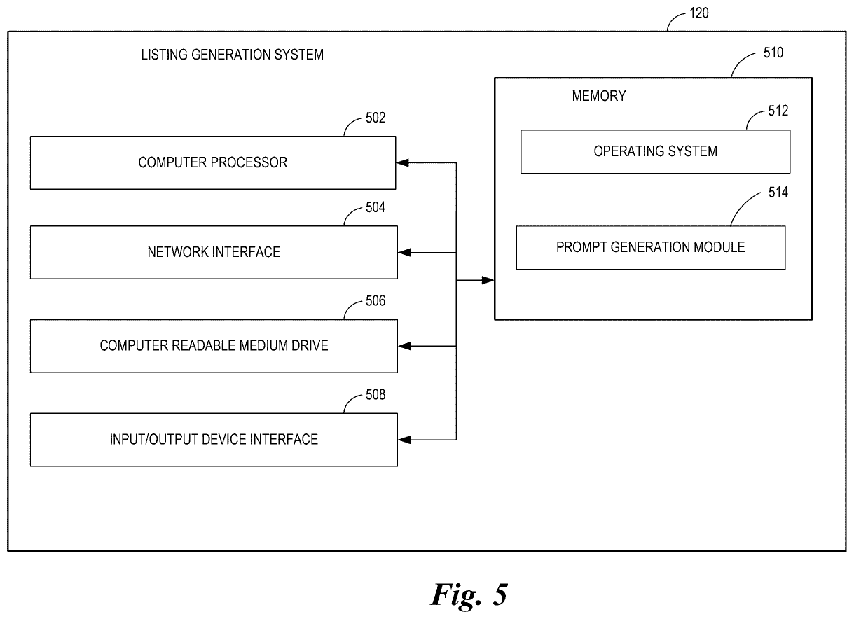

When a routine described herein (e.g., routine 400) is initiated, a set of executable program instructions stored on one or more non-transitory computer-readable media (e.g., hard drive, flash memory, removable media, etc.) may be loaded into memory (e.g., random access memory or RAM) of a computing device, such as the memory of the listing generation system 120 shown in FIG. 5, and executed by one or more processors. In some embodiments, the routine 400, or portions thereof, may be implemented on multiple processors, serially or in parallel.

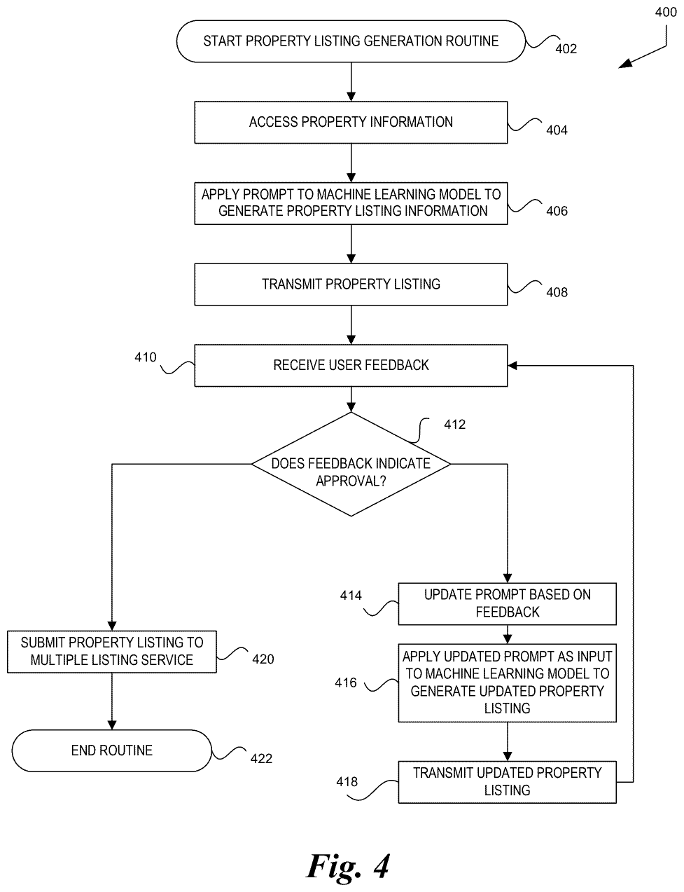

FIG. 4 illustrates example routine 400 for generating a property listing using a listing generation system 120. In some embodiments, portions of the routine 400 may be executed to generate property listing information instead of an entire property listing. For example, an existing property listing may be missing a natural language description, or a user may want an improved natural language description, and a portion of the routine 400 may be performed to generate the natural language description. The routine 400 begins at block 402, for example, in response to a request to generate a property listing, or property listing information, for a property. A property may refer to a lot or parcel of land including any buildings or structures thereon, a building or structure, or a portion of a building or structure (e.g., a condominium, office space, apartment, shed, etc.). The request may include information in one or more modalities, for example text, images, video, or multimodal information. The request may be generated through an iterative or conversational process between the user device 110 and the listing generation system 120, where an initial request is received by the listing generation system 120 from the user device 110, and the user device 110 then provides a set of instructions in order to cause the user device 110, or a user of the user device 110, to provide additional information useful for generating a property listing.

At block 404, the listing generation system 120 accesses property information from a data services system 140. To access the property information, the listing generation system 120 may provide a property identifier (e.g., location data received from the user device 110, a location determined based on information received from the user device 110, etc.), or location information, to the data services system 140 to cause the data services system 140 to search at least one data store 145 to identify information related to the location or property. The data services system 140 may then transmit or otherwise make the identified information accessible to the listing generation system 120.

At block 406, the listing generation system 120 applies a prompt as input to a machine learning model of the machine learning model system 160 to cause the machine learning model system 160 to generate property listing information. While the description of the routine 400, and block 406, describes certain information being provided to a machine learning model of the machine learning model system 160, in some embodiments one or more machine learning models may be executed on the user device 110 without additional communication with the listing generation system 120 or the machine learning model system 160. For example, the user device 110 may receive a machine learning model from the machine learning model system 160 or the listing generation system 120 and execute the machine learning model on the user device 110 based on information generated by the user device 110.

The property listing information generated by the machine learning model may be combined to generate a property listing. Examples of property listing information that may be generated include a description of individual rooms of a structure, a portion of a structure exterior (e.g., a roof, garage, air conditioning unit, etc.), a general description of a property, a general description of a structure on a property, a natural language remark written to encourage a prospective buyer to take interest in the property (e.g., “escape the city life to this beautiful country manor”), or other portions of a property listing (e.g., the portions shown and described in relation to FIG. 6 below herein).

The prompt may indicate a preferred machine learning model of the machine learning model system 160 to use to generate the property listing information. In some embodiments, a machine learning model of the machine learning model system 160 may be trained to generate property listing information for a multiple listing service system 130, and in response to input information from the listing generation system 120 will output high quality and properly formatted property listing information. The prompt may be generated by the listing generation system 120. The prompt may include information in one or more modalities (e.g., image, text, audio, etc.). In some embodiments, information in a first modality (e.g., audio) may be converted to a second modality (e.g., text) to be included in the prompt. The prompt may include the information accessed in the data services system 140, information received from the user device 110, or additional information provided by the listing generation system 120 (e.g., a listing format for a multiple listing service system 130, one or more examples of property listings conforming to the listing format of the multiple listing service system 130, one or more example property listings identified as being high quality property listings, etc.).

Further, to generate the prompt, the listing generation system 120 may communicate with the machine learning model system 160 to use various machine learning models configured to provide information useful for generating the prompt (e.g., a voice to text conversion model trained to generate a transcript from audio information comprising a user's utterance). Multiple machine learning models of the machine learning model system 160 may also be used to generate different portions of a property listing (e.g., a first machine learning model may generate a bulleted list of property highlights and a second machine learning model may generate a description of the property). The machine learning model system 160 or listing generation system 120 may then combine the portions of the property listing to generate a complete property listing.

For example, the listing generation system 120 may provide an image received from the user device 110 as input to a classifier machine learning model of the machine learning model system 160 configured to classify a room type based on an image. In another example, the listing generation system 120 may provide an image as input to a machine learning model configured to identify objects in the image (e.g., fixtures, windows, appliances, etc.). In a further example, the listing generation system 120 may provide an image to a machine learning model of the machine learning model system 160 configured to determine a square footage or other measurement information for a space shown in the image. In some embodiments, the square footage or other measurement information may be used to generate a floor plan for a room, or for a property. The square footage or other measurement information may be determined based on information provided by the user device 110, for example image information, position information (e.g., an angle of the user device 110, a compass direction of the user device 110, GPS information, etc.), LIDAR information, or other information that may be generated by the user device and provided to the listing generation system 120. In another example, the listing generation system 120 may provide an image to a machine learning model to determine a room type (e.g., bedroom, bathroom, living room, kitchen, garage, shed, storage room, unfinished basement, etc.).

In some embodiments, the listing generation system may use multiple machine learning models in series to generate property listing information. For example, a first machine learning model may be provided with image information as input. The first machine learning model may determine that the room represented by the image information is a kitchen. The first machine learning model may further determine that the image indicates the presence of an oven. The output of the first machine learning model indicating the image information represents a kitchen and that there is an oven in the kitchen may be provided to the listing generation system 120. The listing generation system may then provide the output of the first machine learning model, and a transcript of a user utterance captured by the user device 110 to a second machine learning model as input. The transcript of the user utterance may indicate that there is a “convection oven” in the house. The second machine learning model may then determine that the user utterance referring to the “convection oven” is likely referring to the oven determined to be present in the kitchen by the first machine learning model, and update the property listing information for appliances in the house to indicate that there is a convection oven. Such updating of property listing information based on multiple input types that may be received in different modalities improves the overall quality and accuracy of the generated property listing information, advantageously reducing the computational resources that would be needed to allow the user to correct the information manually, and reducing the time needed to generate a property listing.

Additionally, the listing generation system 120 may generate a three-dimensional floorplan for a room or plurality of rooms. The generated three-dimensional floorplan may be useful, for example, in generating a virtual tour of at least a portion of a property. The three-dimensional floorplan may be used to determine square footage information, or other information related to interior dimensions of a room. While images have been used in the preceding example, information in an alternative modality, such as video, text, or audio, may be used to cause generation of the information useful for generating the prompt. The property listing information output generated by the machine learning model of the machine learning model system 160 will be properly formatted for the multiple listing service system 130. The property listing information may also be generated to be similar to high quality listings that are more likely to lead to the sale of a property in general, sale of a property within a shorter than average timeframe, or the sale of a property at a relatively higher price. The generated property listing information may also include a suggested list price. The generated property listing information may also include a virtual tour generated based on images or video received from the user device 110 at block 402, for example images a user of the user device 110 captures based on instructions received from the listing generation system 120, or based on LIDAR information captured by the user device 110.

At block 408, the listing generation system 120 transmits the property listing to the user device 110. Transmitting the property listing to the user device 110 may cause the user device 110 to display the property listing to a user for review, modification, or approval. When reviewing, the user may provide feedback to the listing generation system 120.

At block 410, the listing generation system 120 receives feedback from the user device 110. The feedback may include requests to alter at least a portion of the property listing, additional information (e.g., additional location information, additional images, additional voice notes, etc.), or a request to reformat at least a portion of the property listing (e.g., list the kitchen information before the bedroom information). Alternatively, the feedback may indicate that the property listing is acceptable to the user.

At decision block 412, the listing generation system 120 determines whether the feedback indicates approval of the generated property listing. If the feedback indicates approval, the routine 400 moves to block 420. Otherwise, the routine 400 moves to block 414.

At block 414, the listing generation system 120 updates the prompt to cause the machine learning model of the machine learning model system 160 to generate an updated property listing. The previously-generated property listing may be provided with the prompt, or the machine learning model system 160 may store previous responses transmitted to the listing generation system 120 and include such stored responses in the input to the machine learning model generating the updated property listing. The machine learning model used to generate the updated property listing may be the same or different from the machine learning model that generated the previous property listing. The updated prompt may indicate a preferred machine learning model to generate the property listing.

At block 416, the listing generation system 120 applies the prompt as input to the machine learning model system 160 to cause a machine learning model of the machine learning model system 160 to generate the updated property listing. Additionally, as described above, multiple machine learning models may be used to generate a single property listing, such as by generating different portions of the property listing. The machine learning model system 160 or listing generation system 120 may then combine the separately generated portions to generate a whole updated property listing. Applying the prompt causes the machine learning model to generate the updated property listing, and the machine learning model system 160 to transmit the updated property listing to the listing generation system 120.

At block 418, the listing generation system 120 transmits the updated property listing to the user device 110 for review, as described previously in relation to block 408.

At block 420, the listing generation system 120 submits the generated property listing to a multiple listing service provided by the multiple listing service system 130. In some embodiments, the listing generation system 120 may transmit the generated property listing, or property listing information to a storage location for property listings or property listing information (e.g., a storage system associated with a realtor or group of realtors). In some embodiments, transmitting the generated property listing, or property listing information, may be performed automatically by the listing generation system 120 without user input. Further, transmitting the generated property listing or property listing information may cause an existing property listing, or existing stored property listing information, to be automatically updated without user intervention or interaction. For example, the listing generation system 120 may interact with an existing property listing system (e.g., through an application programming interface of a multiple listing service) to generate or update an existing property listing associated with a property. In some embodiments, the listing generation system 120 may convert at least a portion of the property listing information to conform with a schema used by the existing property listing system (e.g., a format of information used by a multiple listing service system 130). When the generated property listing has been submitted to the multiple listing service system 130, the routine 400 moves to block 422 and ends.

### Execution Environment

FIG. 5 illustrates various components of an example listing generation system 120 configured to implement various functionality described herein.

In some embodiments, the listing generation system 120 may be implemented using any of a variety of computing devices, such as server computing devices, desktop computing devices, personal computing devices, mobile computing devices, mainframe computing devices, midrange computing devices, host computing devices, or some combination thereof.

In some embodiments, the features and services provided by the listing generation system 120 may be implemented as web services consumable via one or more communication networks. In further embodiments, the listing generation system 120 is provided by one or more virtual machines implemented in a hosted computing environment. The hosted computing environment may include one or more rapidly provisioned and released computing resources, such as computing devices, networking devices, and/or storage devices. A hosted computing environment may also be referred to as a “cloud” computing environment.

In some embodiments, as shown, a listing generation system 120 may include: one or more computer processors 502, such as physical central processing units (“CPUs”); one or more network interfaces 504, such as a network interface cards (“NICs”); one or more computer readable medium drives 506, such as a high density disk (“HDDs”), solid state drives (“SSDs”), flash drives, and/or other persistent non-transitory computer readable media; one or more input/output device interfaces 508; and one or more computer-readable memories 510, such as random access memory (“RAM”) and/or other volatile non-transitory computer readable media.

The computer-readable memory 510 may include computer program instructions that one or more computer processors 502 execute and/or data that the one or more computer processors 502 use in order to implement one or more embodiments. For example, the computer-readable memory 510 can store an operating system 512 to provide general administration of listing generation system 120. As another example, the computer readable memory 510 can store a prompt generation module 514 for generating prompts to cause a machine learning model to generate a property listing based on the information received or accessed by the listing generation system 120.

### Example User Interfaces

FIG. 6 illustrates an example user interface 600 for presenting a property listing generated by the listing generation system 120. The user interface 600 of this example includes a display option 602, menu options 604, basic listing information 606, general property information 608, additional property information 610, association information 612, a natural language description 614, a set of listing management options 616, and a property address 618. Each portion of the property listing generated in the user interface 600 includes various types of property listing information that may be generated as described above (e.g., in relation to FIGS. 3 and 4) herein.

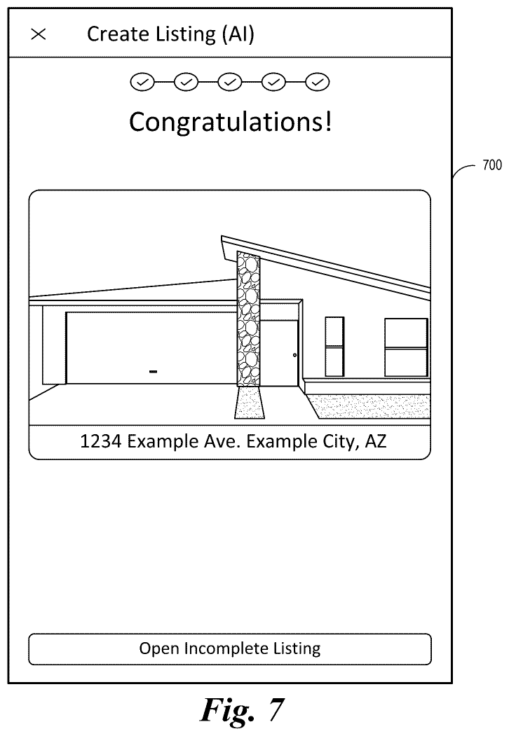

FIG. 7 illustrates an example user interface 700 for indicating a property listing generation has been completed. The user interface 700 may be displayed via a display of the user device 110 after a generated property listing, or property listing information, has been transmitted from the listing generation system 120 to a multiple listing service system 130.

### Terminology

All of the methods and tasks described herein may be performed and fully automated by a computer system. The computer system may, in some cases, include multiple distinct computers or computing devices (e.g., physical servers, workstations, storage arrays, cloud computing resources, etc.) that communicate and interoperate over a network to perform the described functions. Each such computing device typically includes a processor (or multiple processors) that executes program instructions or modules stored in a memory or other non-transitory computer-readable storage medium or device (e.g., solid state storage devices, disk drives, etc.). The various functions disclosed herein may be embodied in such program instructions, or may be implemented in application-specific circuitry (e.g., ASICs or FPGAs) of the computer system. Where the computer system includes multiple computing devices, these devices may, but need not, be co-located. The results of the disclosed methods and tasks may be persistently stored by transforming physical storage devices, such as solid-state memory chips or magnetic disks, into a different state. In some embodiments, the computer system may be a cloud-based computing system whose processing resources are shared by multiple distinct business entities or other users.

Depending on the embodiment, certain acts, events, or functions of any of the processes or algorithms described herein can be performed in a different sequence, can be added, merged, or left out altogether (e.g., not all described operations or events are necessary for the practice of the algorithm). Moreover, in certain embodiments, operations or events can be performed concurrently, e.g., through multi-threaded processing, interrupt processing, or multiple processors or processor cores or on other parallel architectures, rather than sequentially.

The various illustrative logical blocks, modules, routines, and algorithm steps described in connection with the embodiments disclosed herein can be implemented as electronic hardware, or combinations of electronic hardware and computer software. To clearly illustrate this interchangeability, various illustrative components, blocks, modules, and steps have been described above generally in terms of their functionality. Whether such functionality is implemented as hardware, or as software that runs on hardware, depends upon the particular application and design conditions imposed on the overall system. The described functionality can be implemented in varying ways for each particular application, but such implementation decisions should not be interpreted as causing a departure from the scope of the disclosure.

Moreover, the various illustrative logical blocks and modules described in connection with the embodiments disclosed herein can be implemented or performed by a machine, such as a processor device, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A processor device can be a microprocessor, but in the alternative, the processor device can be a controller, microcontroller, or state machine, combinations of the same, or the like. A processor device can include electrical circuitry configured to process computer-executable instructions. In another embodiment, a processor device includes an FPGA or other programmable device that performs logic operations without processing computer-executable instructions. A processor device can also be implemented as a combination of computing devices, e.g., a combination of a DSP and a microprocessor, a plurality of microprocessors, one or more microprocessors in conjunction with a DSP core, or any other such configuration. Although described herein primarily with respect to digital technology, a processor device may also include primarily analog components. For example, some or all of the algorithms described herein may be implemented in analog circuitry or mixed analog and digital circuitry. A computing environment can include any type of computer system, including, but not limited to, a computer system based on a microprocessor, a mainframe computer, a digital signal processor, a portable computing device, a device controller, or a computational engine within an appliance, to name a few.

The elements of a method, process, routine, or algorithm described in connection with the embodiments disclosed herein can be embodied directly in hardware, in a software module executed by a processor device, or in a combination of the two. A software module can reside in RAM memory, flash memory, ROM memory, EPROM memory, EEPROM memory, registers, hard disk, a removable disk, a CD-ROM, or any other form of a non-transitory computer-readable storage medium. An exemplary storage medium can be coupled to the processor device such that the processor device can read information from, and write information to, the storage medium. In the alternative, the storage medium can be integral to the processor device. The processor device and the storage medium can reside in an ASIC. The ASIC can reside in a user terminal. In the alternative, the processor device and the storage medium can reside as discrete components in a user terminal.

Conditional language used herein, such as, among others, “can,” “could,” “might,” “may,” “e.g.,” and the like, unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without other input or prompting, whether these features, elements and/or steps are included or are to be performed in any particular embodiment. The terms “comprising,” “including,” “having,” and the like are synonymous and are used inclusively, in an open-ended fashion, and do not exclude additional elements, features, acts, operations, and so forth. Also, the term “or” is used in its inclusive sense (and not in its exclusive sense) so that when used, for example, to connect a list of elements, the term “or” means one, some, or all of the elements in the list.

Disjunctive language such as the phrase “at least one of X, Y, Z,” unless specifically stated otherwise, is otherwise understood with the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present.

Unless otherwise explicitly stated, articles such as “a” or “an” should generally be interpreted to include one or more described items. Accordingly, phrases such as “a device configured to” are intended to include one or more recited devices. Such one or more recited devices can also be collectively configured to carry out the stated recitations. For example, “a processor configured to carry out recitations A, B and C” can include a first processor configured to carry out recitation A working in conjunction with a second processor configured to carry out recitations B and C.

While the above detailed description has shown, described, and pointed out novel features as applied to various embodiments, it can be understood that various omissions, substitutions, and changes in the form and details of the devices or algorithms illustrated can be made without departing from the spirit of the disclosure. As can be recognized, certain embodiments described herein can be embodied within a form that does not provide all of the features and benefits set forth herein, as some features can be used or practiced separately from others. The scope of certain embodiments disclosed herein is indicated by the appended claims rather than by the foregoing description. All changes which come within the meaning and range of equivalency of the claims are to be embraced within their scope.

What is claimed is:

1. A computer-implemented method comprising:
receiving property information;
generating a prompt for a machine learning model comprising at least a portion of the property information;
applying the prompt as input to a machine learning model to cause the machine learning model to generate property listing information;
transmitting the property listing information;
based on transmitting the property listing information, receiving a response associated with the property listing information;
based on the response, modifying the prompt to generate a modified prompt;
applying the modified prompt as input to the machine learning model to cause the machine learning model to generate updated property listing information; and
automatically updating a property listing based on the updated property listing information.

2. The computer-implemented method of claim 1 further comprising:
generating information to cause display of a graphical user interface; and
receiving, via the graphical user interface, an image comprising image information for a portion of a property,
wherein the property information comprises the image information.

3. The computer-implemented method of claim 2, wherein the image information comprises LIDAR information generated by a LIDAR of a user device.

4. The computer-implemented method of claim 2 further comprising:
generating a floor plan based on image information,
wherein the floor plan is generated, based in part, on the image, and wherein the property information further comprises the floor plan.

5. The computer-implemented method of claim 2 further comprising:
receiving a first image comprising image information for a first portion of a room of a structure;
generating a first portion of a model of the room based on the first image;
based on the generated first portion, displaying, via the user interface, an instruction indicating a user is to capture a second image comprising image information for a second portion of the room, wherein at least a portion of the second image is different from the first image;
receiving the second image;
generating a second portion of the model of the room based in part on the second image and the first portion of the model;
combining the first portion and the second portion of the model of the room to generate a combined model; and
displaying, via the user interface, the combined model.

6. The computer-implemented method of claim 5, wherein the first image comprises first image information generated by a camera, and wherein the second image comprises second image information generated by a LIDAR.

7. The computer-implemented method of claim 6 further comprising identifying, based on at least one of the first image or the second image, at least one of an appliance or fixture in the room.

8. The computer-implemented method of claim 2 further comprising:
applying the image information as input to a second machine learning model trained to identify fixtures represented in image information to cause the second machine learning to identify a fixture represented in the image; and
based on the identified fixture, generating second property listing information.

9. The computer-implemented method of claim 8 further comprising receiving a user utterance as audio information, wherein the second machine learning model is a multimodal model, wherein the second machine learning model is further trained to identify fixtures based on multimodal input information, wherein applying the image information as input to the second machine learning model further comprises applying the audio information as input to the second machine learning model, and wherein the fixture is further identified based in part on the audio information.

10. The computer-implemented method of claim 1, wherein the response comprises second property information associated with the property information, wherein the property information is in a first modality, and wherein the second property information is in a second modality different from the first modality.

11. A system comprising:
a computer-readable memory that store computer-executable instructions; and
one or more processors in communication with the memory, wherein the computer-executable instructions, when executed by the one or more processors, causes the one or more processors to at least:
receive property information;
generate a prompt for a machine learning model comprising at least a portion of the property information;
apply the prompt as input to a machine learning model to cause the machine learning model to generate property listing information;
transmit the property listing information;
based transmitting the property listing information, receive a response associated with the property listing information;
based on the response, modify the prompt to generate a modified prompt;
apply the modified prompt as input to the machine learning model to cause the machine learning model to generate updated property listing information; and
automatically update a property listing based on the updated property listing information.

12. The system of claim 11, wherein the computer-executable instructions, when executed, further cause the one or more processors to:
generate information to cause display of a graphical user interface; and
receive, via the graphical user interface, an image comprising image information for a portion of a property,
wherein the property information comprises the image information.

13. The system of claim 12, wherein the computer-executable instructions, when executed, further cause the one or more processors to:
receive a first image comprising image information for a first portion of a room of a structure;
generate, based on the first image, a first portion of a model of the room;
based on the generated first portion, display, via the user interface, an instruction indicating a user is to capture a second image comprising image information for a second portion of the room, wherein at least a portion of the second image is different from the first image;
receive the second image;
generate, based in part on the second image, a second portion of the model of the room;
combine the first portion and the second portion of the model of the room to generate a combined model; and
display, via the user interface, the combined model.

14. The system of claim 13, wherein the first image comprises image information generated by a camera, and wherein the second image comprises image information generated by a LIDAR.

15. The system of claim 12, wherein the image information comprises LIDAR information generated by a LIDAR of a user device.

16. A non-transitory computer-readable medium encoded with instructions executable by a processor of a computing device, wherein the instructions, when executed by the processor, cause the computing device to at least:
receive property information;
generate a prompt for a machine learning model comprising at least a portion of the property information;
apply the prompt as input to a machine learning model to cause the machine learning model to generate property listing information;
transmit the property listing information;
based transmitting the property listing information, receive a response associated with the property listing information;
based on the response, modify the prompt to generate a modified prompt;
apply the modified prompt as input to the machine learning model to cause the machine learning model to generate updated property listing information; and
automatically update a property listing based on the updated property listing information.

17. The non-transitory computer-readable medium of claim 16, wherein the instructions, when executed by the processor, further cause the device to:
generate information to cause display of a graphical user interface; and
receive, via the graphical user interface, an image comprising image information for a portion of a property,
wherein the property information comprises the image information.

18. The non-transitory computer-readable medium of claim 17, wherein the instructions, when executed by the processor, further cause the device to:
apply the image information as input to a second machine learning model trained to identify fixtures represented in image information to cause the second machine learning to identify a fixture represented in the image; and
based on the identified fixture, generate second property listing information.

19. The non-transitory computer-readable medium of claim 18, wherein the instructions, when executed by the processor, further cause the device to receive a user utterance as audio information, wherein the second machine learning model is a multimodal model, wherein the second machine learning model is further trained to identify fixtures based on multimodal input information, wherein applying the image information as input to the second machine learning model further comprises applying the audio information as input to the second machine learning model, and wherein the fixture is further identified based in part on the audio information.

20. The non-transitory computer-readable medium of claim 16, wherein the response comprises second property information associated with the property information, wherein the property information is in a first modality, and wherein the second property information is in a second modality different from the first modality.
